(19) United States
(12) Patent Application Publication
(10) Pub. No.: US 2010/0238619 A1
(43) Pub. Date: Sep. 23, 2010

(54) ELECTRONIC APPARATUS

(76) Inventor: Hideo Shirasaka, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/692,947

(22) Filed: Jan. 25, 2010

(30) Foreign Application Priority Data
Mar. 19, 2009 (JP) 2009-067808

(51) Int. Cl. H05K 7/20; G06F 1/20

(52) U.S. Cl. 361/679.08; 361/679.47; 361/679.54; 361/679.48; 361/697; 361/702; 361/695

(57) ABSTRACT

According to one embodiment, an electronic apparatus includes a heat sink, a housing, and a cover. The housing contains the heat sink, and includes a first wall, a second wall located opposite to the first wall relative to the heat sink, a third wall extending between the first wall and second wall, and an open portion formed by continuously cutting out the first, second, and third walls. The cover includes a first portion which joins with the first wall and faces at least a part of the heat sink, a second portion which joins with the second wall and faces at least a part of the heat sink from a side opposite to the first portion, and a third portion which joins with the third wall.

### CROSS-REFERENCE TO RELATED APPLICATIONS

This application is based upon and claims the benefit of priority from Japanese Patent Application No. 2009-067808, filed Mar. 19, 2009, the entire contents of which are incorporated herein by reference.

### BACKGROUND

1. Field

One embodiment of the present invention relates to an electronic apparatus comprising a cooling structure.

2. Description of the Related Art

An electronic apparatus, such as a notebook computer, comprises a heat sink and a cooling fan for cooling a CPU, for example. The cooling fan draws in extraneous matter such as dust together with air, and expels the dust toward the heat sink. Therefore, if the electronic apparatus is used for an extended time, dust accumulates on the blades of the cooling fan and fins of the heat sink. Accumulation of dust on the heat sink reduces the thermal radiation efficiency of the heat sink.

Jpn. Pat. Appln. KOKAI Publication No. 2007-189183 discloses an electronic apparatus comprising a dust collection member between an outlet of a cooling fan and a heat sink. In the bottom wall of the electronic apparatus, an open portion is formed. The dust collection member is removably attached to the open portion between the outlet of the cooling fan and heat sink.

The open portion of the above patent document is a rectangular aperture provided in the bottom wall. When cleaning the heat sink by inserting a brush or tweezers into such an open portion, dust adhering to a heat sink may be pushed further into the housing so that dust cannot be easily removed.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of an electronic apparatus according to a first embodiment of the present invention;

FIG. 2 is an exemplary cross-sectional view of the electronic apparatus shown in FIG. 1;

FIG. 3 is an exemplary perspective view of a periphery of a cover of the electronic apparatus shown in FIG. 1;

FIG. 4 is an exemplary cross-sectional view showing a state where a cover is attached to the electronic apparatus shown in FIG. 1;

FIG. 5 is an exemplary cross-sectional view showing a state where the cover is detached from the electronic apparatus shown in FIG. 1;

FIG. 6 is an exemplary cross-sectional view showing a state where the cover has been detached from the electronic apparatus shown in FIG. 1;

FIG. 7 is an exemplary cross-sectional view showing modification of the electronic apparatus according to the first embodiment of the present invention;

FIG. 8 is an exemplary cross-sectional view of an electronic apparatus according to a second embodiment of the present invention;

FIG. 9 is an exemplary cross-sectional view of an electronic apparatus according to a third embodiment of the present invention;

FIG. 10 is an exemplary cross-sectional view of an electronic apparatus according to a fourth embodiment of the present invention;

FIG. 11 is an exemplary cross-sectional view of an electronic apparatus according to a fifth embodiment of the present invention;

FIG. 12 is an exemplary cross-sectional view of the electronic apparatus shown in FIG. 11 taken along line F12-F12;

FIG. 13 is an exemplary perspective view of an electronic apparatus according to a sixth embodiment of the present invention;

FIG. 14 is an exemplary perspective view of the electronic apparatus shown in FIG. 13;

FIG. 15 is an exemplary cross-sectional view of the electronic apparatus shown in FIG. 13;

FIG. 16 is an exemplary perspective view of an electronic apparatus according to a seventh embodiment of the present invention; and

FIG. 17 is an exemplary cross-sectional view showing modification of the electronic apparatus according to the seventh embodiment of the present invention.

### DETAILED DESCRIPTION

Various embodiments according to the invention will be described hereinafter with reference to the accompanying drawings. In general, according to one embodiment of the invention, an electronic apparatus comprises a heat sink; a housing; and a cover. The housing contains the heat sink. The housing comprises a first wall, a second wall located opposite to the first wall relative to the heat sink, a third wall extending between the first wall and second wall, and an open portion formed by continuously cutting out the first, second, and third walls and configured to expose at least a part of the heat sink to the outside. The cover is detachably attached to the open portion. The cover comprises a first portion which joins with the first wall and faces at least a part of the heat sink, and a second portion which joins with the second wall and faces at least a part of the heat sink from a side opposite to the first portion, and a third portion which joins with the third wall.

Hereinafter, embodiments of the present application will be described based on the drawings applied to a notebook computer.

### First Embodiment

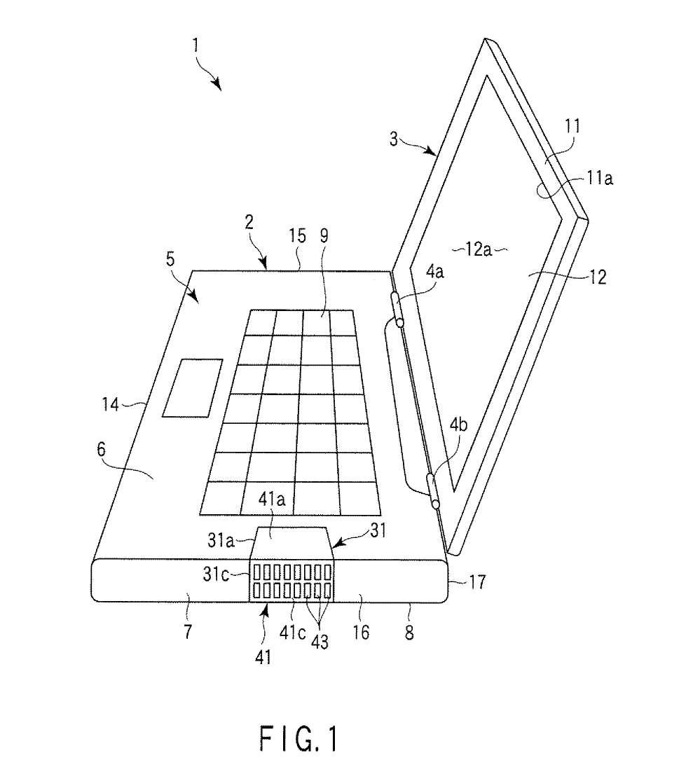

FIGS. 1-6 disclose an electronic apparatus 1 according to a first embodiment of the present invention. The electronic apparatus 1 is, for example, a notebook computer. The present invention is not limited to a notebook computer, and widely applicable to various electronic apparatuses comprising a mobile electronic terminal, a desktop computer and a game machine.

The electronic apparatus 1 comprises a main unit 2, a display unit 3, and a hinge unit 4a, 4b. The main unit 2 is an electronic apparatus main body in which a main board is installed. The main unit 2 comprises a housing 5 shaped like a flat box. The housing 5 comprises an upper wall 6, a peripheral wall 7 and a lower wall 8 (bottom wall). When the electronic apparatus 1 is placed on a work surface (for example, a desk), the lower wall 8 faces the work surface. The lower wall 8 expands substantially in parallel with the work surface.

The upper wall 6 expands substantially in parallel with the lower wall 8 with a space therebetween. The upper wall 6 supports a keyboard 9 mounted on the housing 5. The peripheral wall 7 stands relative to the lower wall 8, and connects a peripheral edge portion of the lower wall 8 with a peripheral edge portion of the upper wall 6.

As shown in FIG. 1, the display unit 3 comprises a display housing 11 and a display device 12 contained in the display housing 11. The display device 12 comprises a display screen 12a. The display screen 12a is exposed outside the display housing 11 through an open portion 11a in the front surface of the display housing 11.

The display unit 3 is connected to a rear end portion of the housing 5 by means of, for example, a pair of hinges 4a, 4b. The display unit 3 is swingable from a closed position, in which the display unit 3 covers the upper wall 6 of the housing 5, to an open position, in which the display unit 3 is raised away from the upper wall 6.

The housing 5 of the main unit 2 will be described in detail.

The peripheral wall 7 of the housing 5 comprises a front wall 14, a left wall 15, a right wall 16 and a rear wall 17. The front wall 14 is located on an end portion (front end portion) which is opposite to an end portion on which the hinges 4a, 4b are provided. The front wall 14 extends in a width direction (lateral direction) of the housing 5, and faces a user when the electronic apparatus 1 is used. In this specification, “front” is a user side and “rear” is a side opposite to the user side, and “right” and “left” are sides defined with reference to a user's point of view.

The rear wall 17 is located on the end portion (rear end portion) to which the hinges 4a, 4b are provided. The rear wall 17 extends substantially in parallel with the front wall 14. The left wall 15 extends in a depth direction (longitudinal direction) of the housing 5 so as to connect a left end portion of the front wall 14 with a left end portion of the rear wall 17. The right wall 16 extends in a depth direction (longitudinal direction) of the housing 5 so as to connect a right end portion of the front wall 14 with a right end portion of the rear wall 17.

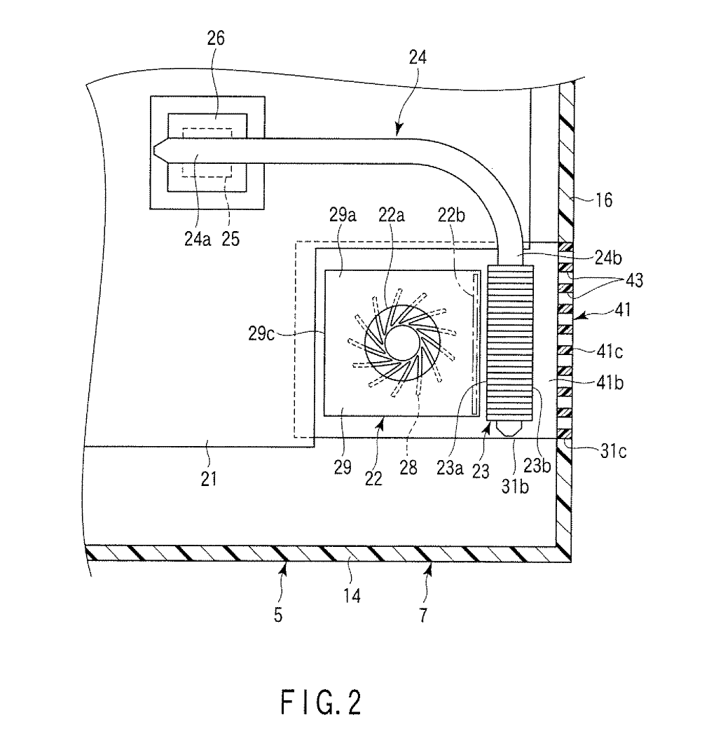

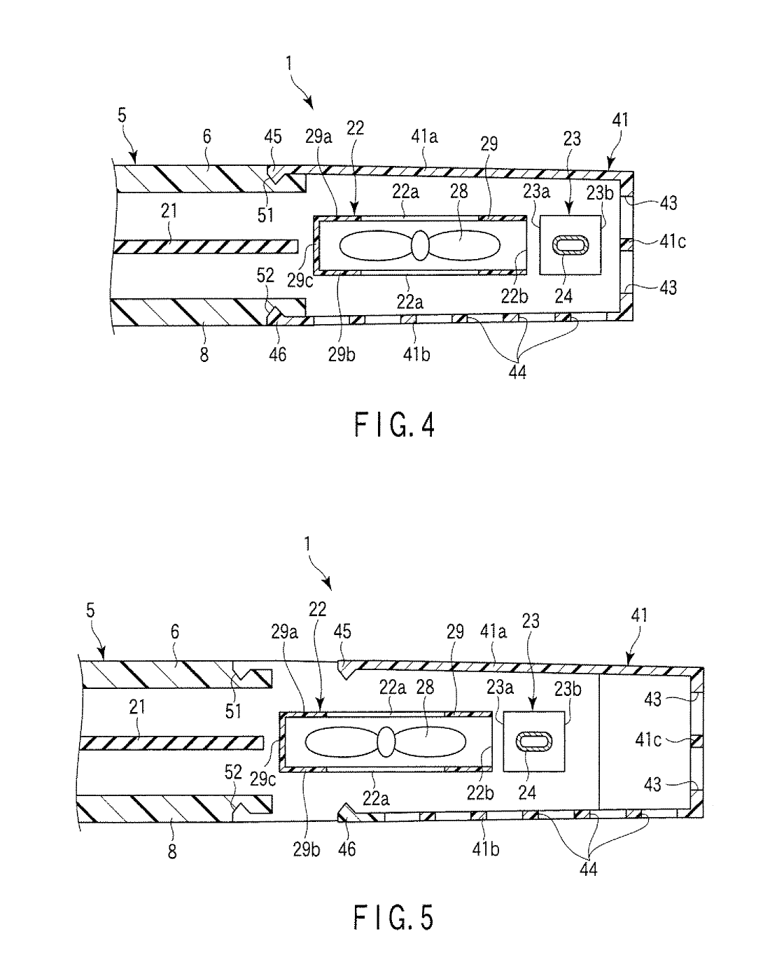

As shown in FIGS. 2 and 4, the housing 5 contains a circuit board 21, a cooling fan 22, a heat sink 23 and a heat transfer member 24. The circuit board 21 is, for example, a main board (motherboard). The circuit board 21 is laid horizontally in the housing 5.

A heat generating member 25 is mounted on the circuit board 21. The heat generating member 25 is an electronic component that generates heat when used. As examples of the heat generating member 25, a CPU, a graphic chip, North Bridge (trademark), and a memory are enumerated. However, the heat generating member 25 is not limited to the above examples, and various members desired to radiate heat corresponds to the heat generating member 25. A heat receiving member 26 made of, for example, a metal plate is thermally connected to the heat generating member 25.

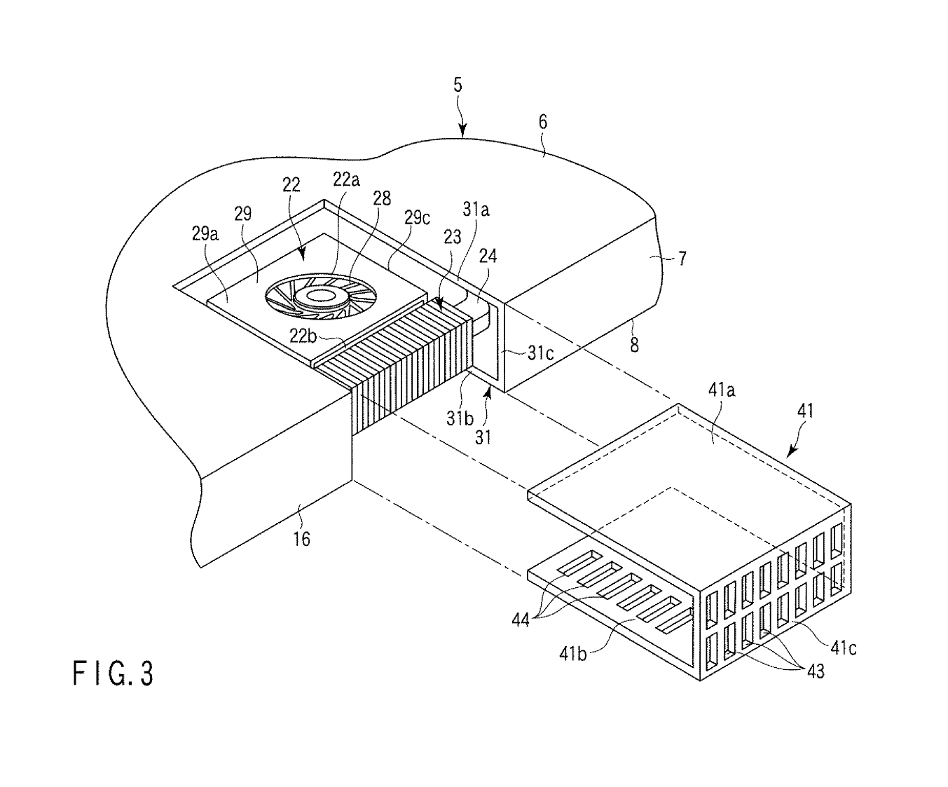

As shown in FIGS. 2 and 3, the cooling fan 22 is a centrifugal fan, and comprises an impeller 28 (fan blades) and a fan case 29. The cooling fan 22 is secured to the housing 5 with a securing structure, which is not shown. The impeller 28 comprises a plurality of blades, is rotated by a motor, which is not shown, and discharges air centrifugally relative to the impeller 28.

The fan case 29 is shaped like a box, and contains the impeller 28. The fan case 29 comprises an upper surface member 29a, a lower surface member 29b, and a side surface member 29c. The upper surface member 29a and lower surface member 29b are provided above or below the impeller 28, and face the impeller 28 axially relative to the impeller 28.

The upper surface member 29a and lower surface member 29b are each shaped like a plate, and expand horizontally. An inlet 22a is formed in each of the upper surface member 29a and lower surface member 29b. The side surface member 29c is an upright wall extending vertically between an edge portion of the upper surface member 29a and an edge portion of the lower surface member 29b. The side surface member 29c comprises an outlet 22b. The outlet 22b is located in a direction of centrifugal force relative to the impeller 28. The cooling fan 22 draws air from within the housing 5 through the inlet 22a, and expels the air to the heat sink 23. In this way, the cooling fan 22 cools the heat sink 23.

As shown in FIGS. 2-4, the heat sink 23 is a fin unit in which a plurality of metal fins are aligned, for example. The heat sink 23 is provided along the outlet 22b of the cooling fan 22 and faces the outlet 22b of the cooling fan 22. The heat sink 23 is provided between the outlet 22b of the cooling fan 22 and exhaust apertures 43 of a cover 41 mentioned later. The heat sink 23 comprises an intake side 23a facing the outlet 22b of the cooling fan 22 and an exhaust side 23b facing the exhaust apertures 43 of the cover 41.

An example of the heat transfer member 24 is a heat pipe. The heat transfer member 24 comprises a heat receiving part 24a and a heat radiating part 24b. The heat receiving part 24a is thermally connected to the heat generating member 25 via the heat receiving member 26. The heat radiating part 24b is thermally connected to the heat sink 23. The heat transfer member 24 transfers part of heat received at the heat receiving end portion 24a to the heat radiating end portion 24b. Namely, the heat transfer member 24 transfers part of heat generated by the heat generating member 25 to the heat sink 23.

As shown in FIG. 4, the upper wall 6 is an example of a “first wall” of the present invention. The upper wall 6 is located above the heat sink 23, and substantially horizontally expands. The lower wall 8 is an example of a “second wall” of the present invention. The lower wall 8 is located below the heat sink 23, and substantially horizontally expands. Namely, the lower wall 8 is located opposite to the upper wall 6 relative to the heat sink 23. The right wail 16 is an example of a “third wall” of the present invention. The right wall 16 extends upright between an end portion of the upper wall 6 and an end portion of the lower wall 8.

A part of each of the upper wall 6 and lower wall 8 (i.e., the first and second walls) or the entire upper wall 6 and lower wall 8 may be inclined. The right wall 16 (i.e., the third wall) may be a part of the thickness of the housing 5.

As shown in FIG. 3, the housing 5 comprises an open portion 31. The open portion 31 is formed by continuously cutting out the upper wall 6, lower wall 8, and right wall 16. Namely, the open portion 31 comprises a first cutout 31a formed by cutting out the upper wall 6, a second cutout 31b formed by cutting out the lower wall 8, and a third cutout 31c formed by cutting out the right wall 16. The first to third cutouts are continuous. Accordingly, the open portion 31 is formed continuously in the upper wall 6, right wall 16, and lower wall 8.

As shown in FIGS. 2-4, the open portion 31 is formed to expose at least a part of the heat sink 23 outside the housing 5. The first cutout 31a is located above the heat sink 23 to expose the entire heat sink 23 from above. The second cutout 31b is located below the heat sink 23 to expose the entire heat sink 23 from below. The third cutout 31c is located beside the heat sink 23 to expose the entire heat sink 23 from a side. Accordingly, the entire heat sink 23 is exposed through the open portion 31 in three directions comprising an upward direction, a downward direction and a lateral direction.

Further, the open portion 31 exposes at least a part of the cooling fan 22 outside the housing 5. The first cutout 31a is located above the cooling fan 22 to expose the entire cooling fan 22 from above. The second cutout 31b is located below the cooling fan 22 to expose the entire cooling fan 22 from below. The third cutout 31c is located beside the cooling fan 22 to expose the entire cooling fan 22 from a side. Accordingly, the entire cooling fan 22 is exposed through the open portion 31 in three directions, that is, upward, downward and laterally.

As shown in FIGS. 1-4, a cover 41 that covers the open portion 31 is detachably attached to the open portion 31 of the housing 5. The cover 41 comprises a first portion 41a, second portion 41b, and third portion 41c.

The first portion 41a is fitted (inserted) into the first cutout 31a to join with the upper wall 6. The first portion 41a faces at least a part of the heat sink 23 and at least a part of the cooling fan 22 from above. The first portion 41a according to the present embodiment faces the entire heat sink 23 and entire cooling fan 22 from above, and covers the first cutout 31a. (The expression “join with a wall” according to the present invention means forming one wall surface cooperatively with the wall.)

The second portion 41b is fitted (inserted) into the second cutout 31b to join with the lower wall 8. The second portion 41b faces at least a part of the heat sink 23 and at least a part of the cooling fan 22 from below. Namely, the second portion 41b faces the heat sink 23 and cooling fan 22 from a side opposite the first portion 41a. The second portion 41b according to the present embodiment faces the entire heat sink 23 and entire cooling fan 22 from below, and covers the second cutout 31b.

The third portion 41c is fitted (inserted) into the third cutout 31c to join with the right wall 16. The third portion 41c faces the entire heat sink 23 from a side, and covers the third cutout 31c. Accordingly, the cover 41 is formed to join with the upper wall 6, lower wall 8, and right wall 16 and to have a substantially U-shaped cross section.

As shown in FIG. 4, the third portion 4c comprises, for example, a plurality of exhaust apertures 43. Each exhaust aperture 43 faces the outlet 22b of the cooling fan 22 with the heat sink 23 located therebetween. Air expelled from the cooling fan 22 passes through the heat sink 23 and is exhausted outside the housing 5 from the exhaust aperture 43. In contrast, the second portion 41b comprises, for example, a plurality of intake apertures 44. Each intake aperture 44 is provided below the cooling fan 22 and heat sink 23, for example. When the cooling fan 22 is driven, external air is drawn into the housing 5 through the intake aperture 44. The intake aperture 44 may be provided in the first portion 41a instead of or in addition to the second portion 41b.

As shown in FIG. 5, the first portion 41a of the cover 41 comprises a first male engaging member 45 engaged with the upper wall 6. The first male engaging member 45 is an example of a “first engaging member”. The second portion 41b of the cover 41 comprises a second male engaging member 46 engaged with the lower wall 8. The second male engaging member 46 is an example of a “second engaging member”. The first and second male engaging members are lugs protruding inward relative to the cover 41 to face each other. The cover 41 is, for example, plastic and has elasticity. The housing 5 may be plastic or metal.

As shown in FIG. 5, the upper wall 6 comprises a first female engaging member 51 with which the first male engaging member 45 of the cover 41 is engaged. The lower wall 8 comprises a second female engaging member 52 with which the second male engaging member 46 of the cover 41 is engaged. The first and second female engaging members 51, 52 are concave portions indented inward relative to the housing 5 so as to engage with lugs on the cover 41. As shown in FIG. 4, the cover 41 pushes the first and second male engaging members 45, 46 inward relative to the cover 41 as a result of the elastic force of the cover 41. Namely, the cover 41 pushes the first and second male engaging members 45, 46 onto the first and second female engaging members 51, 52. Consequently, the cover 41 is secured to the housing 5 by the elastic force of the cover 41.

The function of the electronic apparatus 1 will be described.

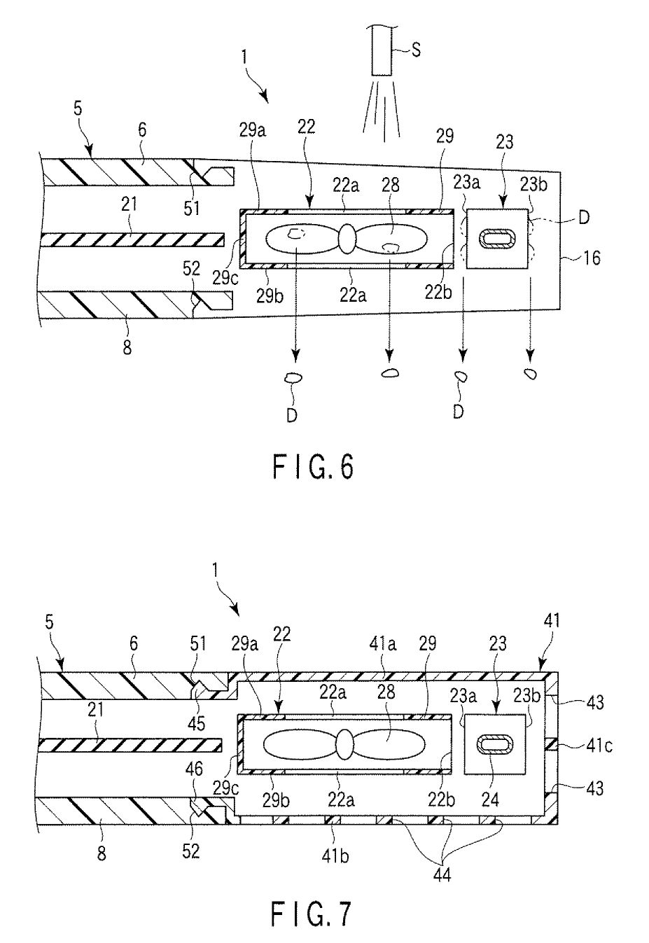

If the electronic apparatus 1 is used for an extended time, dust D accumulates on the cooling fan 22 and heat sink 23. The dust D generally tends to accumulate on the exhaust side 23b and intake side 23a of the heat sink 23 and on the blades of the cooling fan 22 (see FIG. 6).

The dust D can be removed, for example, by a user. By detaching the cover 41 from the housing 5 as shown in FIG. 5, the entire heat sink 23 and entire cooling fan 22 are exposed in three directions, that is, upward, downward, and laterally, as shown in FIG. 6.

In this state, the dust D that has settled on the heat sink 23 and cooling fan 22 is removed by blowing compressed air using, for example, an air spray S, or by cleaning using cleaning tools, such as a brush and tweezers. For example, the heat sink 23 and cooling fan 22 are cleaned from above and the dust D adhering to the heat sink 23 and cooling fan 22 falls off. Consequently, dust D that has been displaced does not remain in the housing 5.

The electronic apparatus 1 having the above configuration makes it possible to easily remove dust D adhering to the heat sink 23 and the cooling fan 22. In other words, the electronic apparatus 1 comprising the open portion 31 formed by continuously cutting out the upper wall 6, lower wall 8, and right wall 16 of the housing 5, and the cover 41 which covers the open portion 31 and is detachably attached to the open portion 31 can expose the heat sink 23 and cooling fan 22 in three directions, that is, upward, downward, and laterally, by removal of the cover 41.

The configuration offers great flexibility for cleaning, and enables detailed direct visual confirmation and direct cleaning of a part on which dust has accumulated. If, for example, the heat sink 23 and cooling fan 22 are cleaned from above, the dust D that has been displaced from the heat sink 23 and cooling fan 22 falls off without remaining in the housing 5.

Unlike the case where cleaning is done by inserting a brush or tweezers into an open portion only on the lower wall of the housing, it is unlikely that dust adhering to a thermal member such as a heat sink is pushed further inward, and the dust can be easily removed.

In the present embodiment, the cover 41 comprises the first male engaging member 45 engaged with the upper wall 6 and the second male engaging member 46 engaged with the lower wall 8, and is secured to the housing by the elastic force of the cover 41. This configuration makes it possible to omit a securing member such as a screw by taking advantage of the shape of the cover 41, reduce the cost of an electronic apparatus and increase the efficiency of assembly work. The cover 41 is not necessarily secured to the housing 5 by elastic force, and may be secured, for example, by a screw.

Referring to FIG. 7, modification of the electronic apparatus 1 according to the first embodiment of the present invention will be described. As shown in FIG. 7, the first and second male engaging members 45, 46 according to the present modification are lugs protruding outward relative to the cover 41. The first and second female engaging members 51, 52 are concave portions indented outward relative to the housing 5 so that the lugs of the cover 41 are engaged by the first and second female engaging members 51, 52.

As shown in FIG. 7, the cover 41 pushes the first and second male engaging members 45, 46 toward the outside of the cover 41, i.e., pushes the first and second male engaging members 45, 46 onto the first and second female engaging members 51, 52. Accordingly, the cover 41 is secured to the housing 5 by the elastic force of the cover 41. This configuration produces the same advantage as the first embodiment.

### Second Embodiment

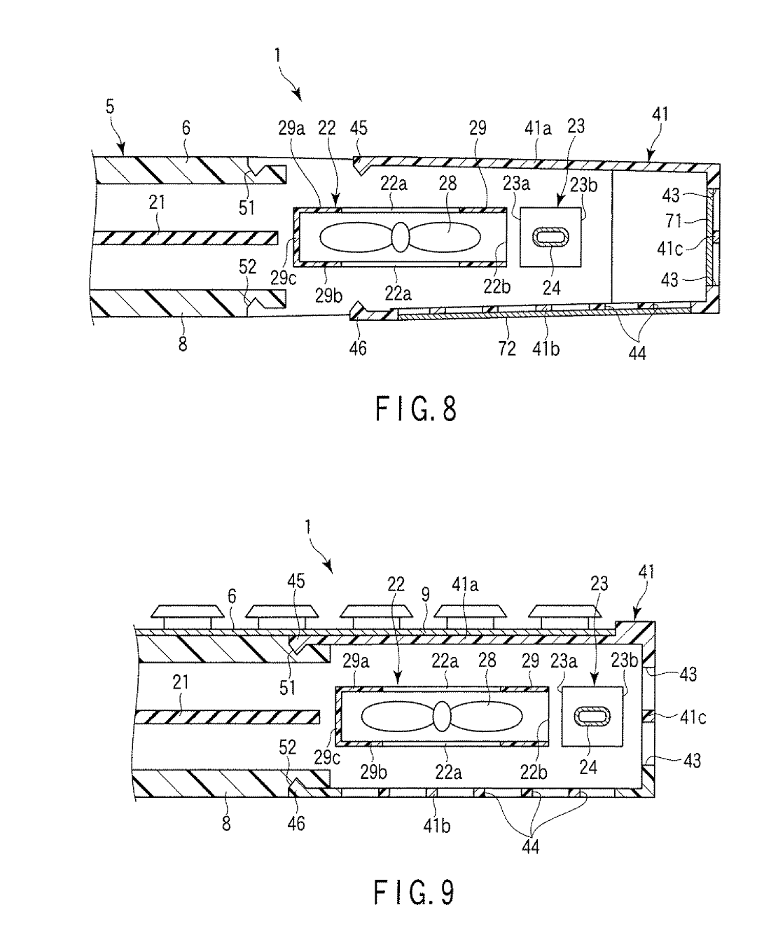

Referring to FIG. 8, the electronic apparatus 1 according to a second embodiment of the present invention will be described. Configurations having functions the same as or similar to those in the first embodiment will be assigned the same reference numbers, and explanations thereof will be omitted. Configurations other than those described below are the same as those in the first embodiment.

As shown in FIG. 8, the cover 41 comprises a first dust filter 71 attached to the exhaust apertures 43 and a second dust filter 72 attached to the intake apertures 44. The intake apertures 44 and exhaust apertures 43 are examples of a “vent” of the present invention.

The first dust filter 71 is attached, for example, to the exhaust apertures 43 on the inside of the housing 5. The second dust filter 72 is attached, for example, to the intake apertures 44 on the outside of the housing 5. The first and second filters 71, 72 are dust collection filters that remove dust in the air passing through the filters.

Like the first embodiment, this configuration makes it possible to easily remove dust adhering to the heat sink 23 and the cooling fan 22. Further, by detaching the cover 41 from the housing 5, the dust filters 71, 72 can be easily cleaned. Consequently, problems such as clogging of the dust filters are prevented, and degradation of the cooling performance of the electronic apparatus 1 is prevented.

In particular, with the configuration in which the cover 41 is detachable from the housing 5, even the dust filter 71 attached to the vent on the inside of the housing 5 can be easily cleaned. The second dust filter 72 may be attached, for example, to the intake apertures 44 on the inside of the housing 5.

### Third Embodiment

Referring to FIG. 9, the electronic apparatus 1 according to a third embodiment will be described. Configurations having functions the same as or similar to those in the first embodiment will be assigned the same reference numbers, and explanations thereof will be omitted. Configurations other than those described below are the same as those in the first embodiment.

As shown in FIG. 9, the first portion 41a of the cover 41 according to the present embodiment is located below the keyboard 9, and supports a part of the keyboard 9 from below. Namely, the first portion 41a of the cover 41 forms a part of a mounting surface on which the keyboard 9 is mounted.

The keyboard 9 is secured to the housing 5 by a keyboard securing member, which is not shown. The keyboard 9 secured to the housing 5 supports the cover 41 so as to prevent the cover 41 from being detached from the housing 5. For example, in the present embodiment, the keyboard 9 pushes the first male engaging member 45 of the cover 41 onto the first female engaging member 51. When the keyboard 9 is detached from the housing 5, the cover 41 becomes removable from the housing 5.

Like the first embodiment, this configuration makes it possible to easily remove dust adhering to the heat sink 23 and the cooling fan 22. Further, if the first portion 41a of the cover 41 is located below the keyboard 9 to support a part of the keyboard 9, the configuration of the present invention can be applied to a relatively small electronic apparatus in which the distance between a side portion (for example, the right wall 16) of the housing 5 and a side edge portion of the keyboard 9 is short. Further, if the keyboard 9 holds the cover 41, the cover 41 is less likely to be accidentally detached from the housing 5.

### Fourth Embodiment

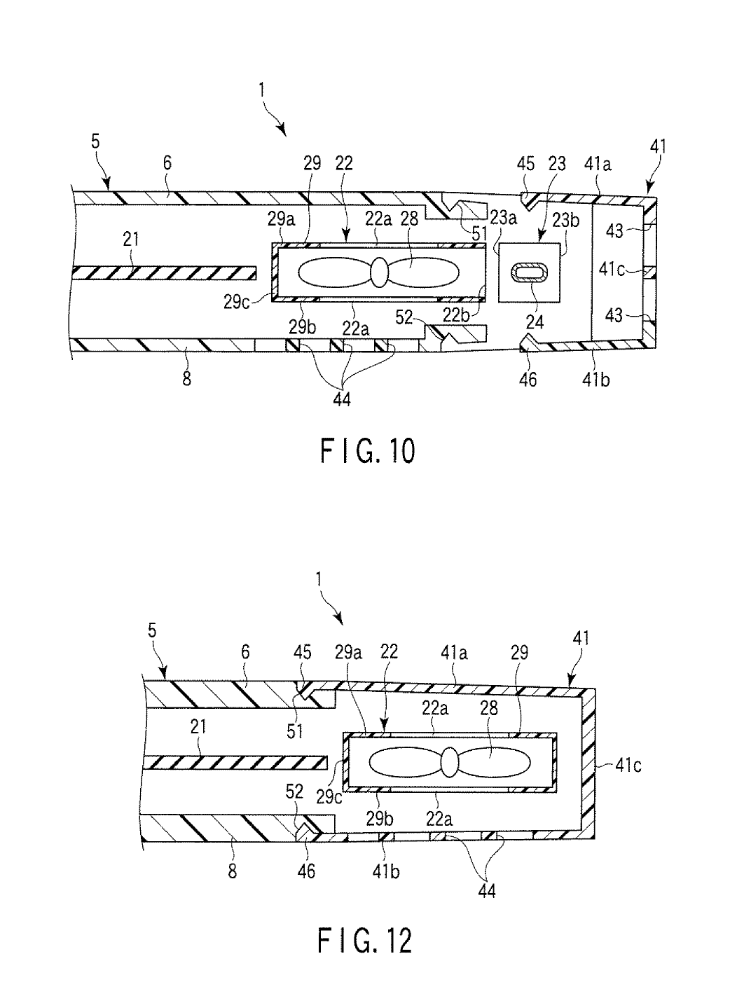

Referring to FIG. 10, the electronic apparatus 1 according to a fourth embodiment will be described. Configurations having functions the same as or similar to those in the first embodiment will be assigned the same reference numbers, and explanations thereof will be omitted. Configurations other than those described below are the same as those in the first embodiment.

As shown in FIG. 10, the first cutout 31a according to the present embodiment is located above the heat sink 23 to expose the entire heat sink 23 from above, but is not located above the cooling fan 22. The second cutout 31b is located below the heat sink 23 to expose the entire heat sink 23 from below, but is not located below the cooling fan 22. The first and second portions 41a, 41b of the cover 41 each face the entire heat sink 23, and do not face the cooling fan 22.

Like the first embodiment, this configuration makes it possible to easily remove dust adhering to the heat sink 23.

### Fifth Embodiment

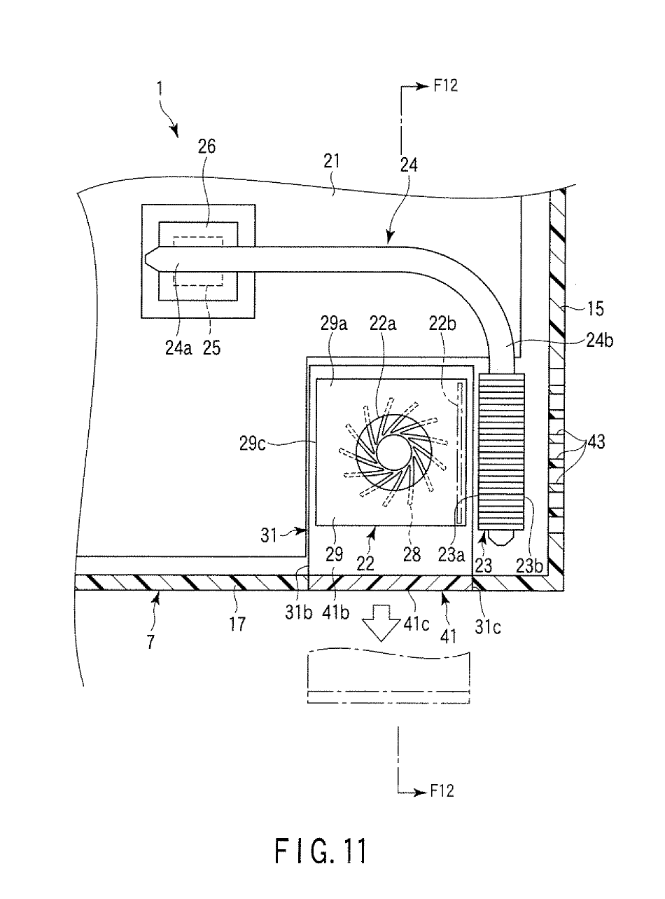

Referring to FIGS. 11 and 12, the electronic apparatus 1 according to a fifth embodiment will be described. Configurations having functions the same as or similar to those in the first embodiment will be assigned the same reference numbers, and explanations thereof will be omitted. Configurations other than those described below are the same as those in the first embodiment.

The rear wall 17 is an example of a “third wall” of the present invention. The rear wall 17 extends between an end portion of the upper wall 6 and an end portion of the lower wall 8 in an upright manner. The rear wall 17 may be a part of the thickness of the housing 5.

As shown in FIGS. 11 and 12, the open portion 31 is provided in the upper wall 6, lower wall 8, and rear wall 17. Namely, the open portion 31 comprises a first cutout 31a formed by cutting out the upper wall 6, a second cutout 31b formed by cutting put the lower wall 8, and a third cutout 31c formed by cutting out the rear wall 17, the first to third cutouts 31a, 31b, 31c being continuous. Accordingly, the open portion 31 is formed continuously in the upper wall 6, rear wall 17, and lower wall 8.

The open portion 31 is formed to expose at least a part of the cooling fan 22 outside the housing 5. The first cutout 31a according to the present embodiment is located above the cooling fan 22 to expose the entire cooling fan 22 from above, and is not located above the heat sink 23. The second cutout 31b is located below the cooling fan 22 to expose the entire cooling fan 22 from below, and is not located below the heat sink 23. The third cutout 31c is located beside the cooling fan 22 to expose the entire cooling fan 22 from a side. Accordingly, in the present embodiment, the entire cooling fan 22 is exposed through the open portion 31 in three directions, that is, upward, downward, and laterally.

The first portion 41a of the cover 41 is fitted into the first cutout 31a and joins with the upper wall 6. The first portion 41a faces the entire cooling fan 22, and does not face the heat sink 23. The second portion 41b is fitted into the second cutout 31b, and joins with the lower wall 8. The second portion 41b faces the cooling fan 22 from a side opposite to the first portion 41a. The second portion 41b faces the entire cooling fan 22, and does not face the heat sink 23. The third portion 41c is fitted into the third cutout 31c, and joins with the rear wall 17. The exhaust apertures 43 are provided in the left wall 15 of the housing 15.

Like the first embodiment, this configuration makes it possible to easily remove dust adhering to the cooling fan 22.

### Sixth Embodiment

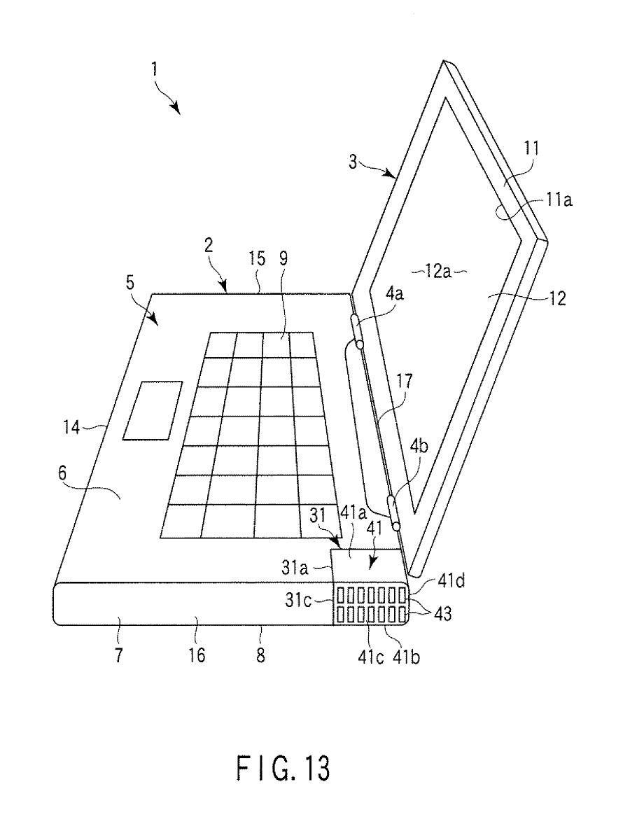

Referring to FIGS. 13-15, the electronic apparatus 1 according to a sixth embodiment will be described. Configurations having functions the same as or similar to those in the first embodiment will be assigned the same reference numbers, and explanations thereof will be omitted. Configurations other than those described below are the same as those in the first embodiment.

As shown in FIG. 13, the rear wall 17 is an example of a “fourth wall” of the present invention. The rear wall 17 extends in a direction intersecting (for example, in a direction orthogonal to) the right wall 16. The rear wall 17 is adjacent to the right wall 16, and extends between an end portion of the upper wall 6 and an end portion of the lower wall 8 in an upright manner. The rear wall 17 forms a corner of the housing 5 cooperatively with the right wall 16. The rear wall 17 may be a part of the thickness of the housing 5.

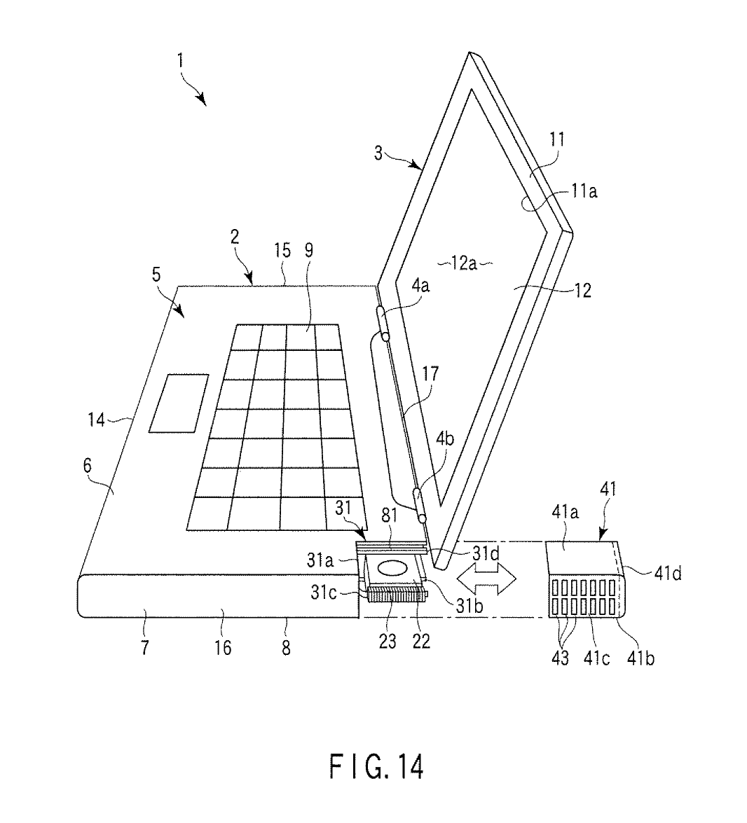

As shown in FIG. 14, the open portion 31 is formed by continuously cutting out the upper wall 6, right wall 16, rear wall 17 and lower wall 8, i.e., is formed by cutting out a corner of the housing 5. Namely, the open portion 31 comprises a first cutout 31a formed by cutting out the upper wall 6, a second cutout 31b formed by cutting out the lower wall 8, a third cutout 31c formed by cutting out the right wall 16, and a fourth cutout 31d formed by cutting out the rear wall 17, and the first to fourth cutouts 31a, 31b, 31c, 31d are continuous. Accordingly, the open portion 31 is formed in the upper wall 6, right wall 16, rear wall 17, and lower wall 8.

As shown in FIG. 14, the cover 41 according to the present embodiment comprises a fourth portion 41d in addition to the first to third portions 41a, 41b, 41c. The fourth portion 41d is fitted (inserted) into the fourth cutout 31d and joins with the rear wall 17. The fourth portion 41d faces the heat sink 23 and cooling fan 22 from a direction different from (for example, orthogonal to) the third portion 31c and covers the fourth cutout 31d. The fourth portion 41d extends in a direction intersecting (for example, a direction orthogonal to) the third portion 41c.

One end portion (edge portion) of the first portion 41a and one end portion of the second portion 41b are connected to each other via the third portion 41c, and supported by the third portion 41c. Another end portion (edge portion) of the first portion 41a and another end portion of the second portion 41b are connected to each other via the fourth portion 41d, and supported by the fourth portion 41d. Namely, the first and second portions 41a, 41b are supported by two walls 41c, 41d extending in different directions.

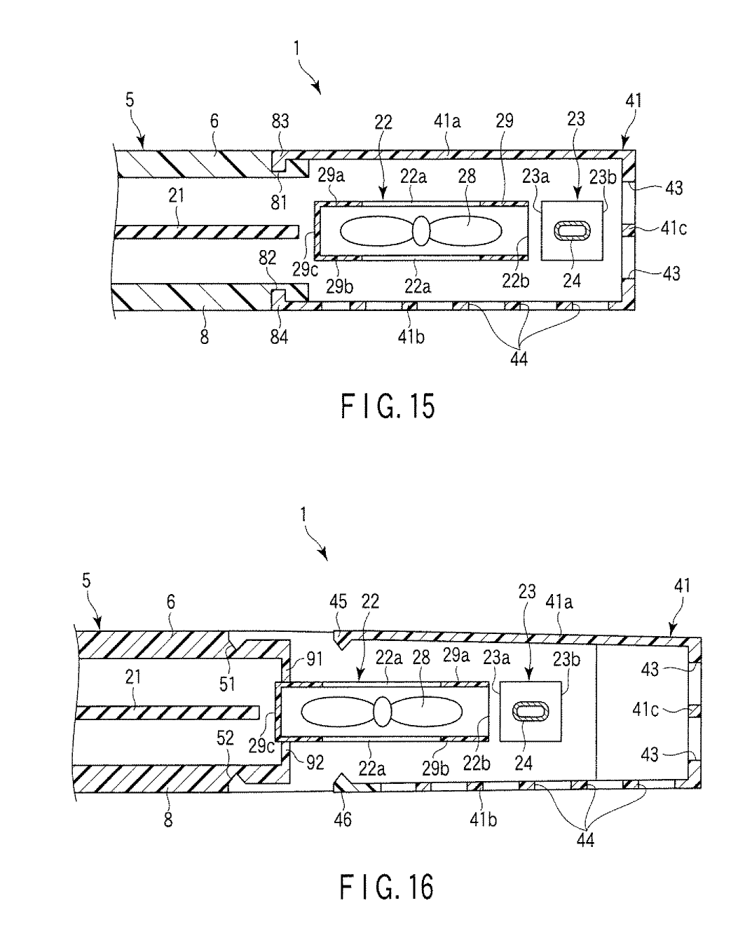

As shown in FIGS. 14 and 15, the upper wall 6 comprises a first guide 81 that guides the first portion of the cover 41. The lower wall 8 comprises a second guide 82 that guides the second portion 41b of the cover 41. The first and second guides 81, 82 each comprise a recess portion extending, for example, depthwise relative to the housing 5, and guide sliding movement of the cover 41.

The first portion 41a of the cover 41 comprises a first slide part 83 guided by the first guide 81. The second portion 41b comprises a second slide part 84 guided by the second guide 82. The first and second slide parts 83, 84 are protruding parts inserted into the recess portions of the guides 81, 82. The cover 41 is guided by the first and second guides 81, 82 in a direction orthogonal to the direction in which the first portion 41a extends from the third portion 41c. The cover 41 is attached to and detached from the open portion 31 by sliding along the first and second guides 81, 82.

Like the first embodiment, this configuration makes it possible to easily remove dust adhering to the heat sink 23 and cooling fan 22. With the configuration in which one end portion (i.e., first end portion) of each of the first and second portions 41a, 41b is supported by the third portion 41c, and another end portion (i.e., second end portion) of each of the first and second portions 41a, 41b is supported by the fourth portion 41d, the supporting structures of the first and second portions 41a, 41b have relatively great rigidity, and stably support the first and second portions 41a, 41b.

Further, the corner of the housing 5 is easily damaged, for example, when the electronic apparatus 1 is accidentally dropped. With the configuration in which the cover 41 is attached to the corner of the housing 5, repair can be made by replacing the damaged cover 41 with a new cover, and the repair cost can be reduced.

With the configuration in which the housing 5 comprises the guides 81, 82 that guide the cover 41, and the cover 41 is attached to and detached from the open portion 31 by being slid along the guides 81, 82, the cover 41 can be easily attached and cleaning efficiency is increased.

### Seventh Embodiment

Referring to FIG. 16, the electronic apparatus 1 according to a seventh embodiment will be described. Configurations having functions the same as or similar to those in the first embodiment will be assigned the same reference numbers, and explanations thereof will be omitted. Configurations other than those described below are the same as those in the first embodiment.

As shown in FIG. 16, the upper wall 6 comprises a first rib 91 extending toward the fan case 29 of the cooling fan 22. The lower wall 8 comprises a second rib 92 extending toward the fan case 29 of the cooling fan 22. The first and second ribs 91, 92 are each located further inside the housing 5 than the inlet 22a of the cooling fan 22, and face a gap between the cooling fan 22 and the inner surface of the housing 5. The first and second ribs 91, 92 are examples of a “raised part” of the present invention, and are wall features that prevent dust on the cooling fan 22 and heat sink 23 disturbed during cleaning from entering the housing 5. The size, position and shape of each of the first and second ribs 91, 92 are determined according to purpose.

Like the first embodiment, this configuration makes it possible to easily remove dust adhering to the heat sink 23 and cooling fan 22. Further, even if a way of cleaning that disturbs dust, such as air-spraying, is adopted as a way of cleaning the cooling fan 22 and heat sink 23, entry of the dust into the housing 5 can be inhibited. The first and second ribs 91, 92 may extend toward the circuit board 21 instead of toward the cooling fan 22.

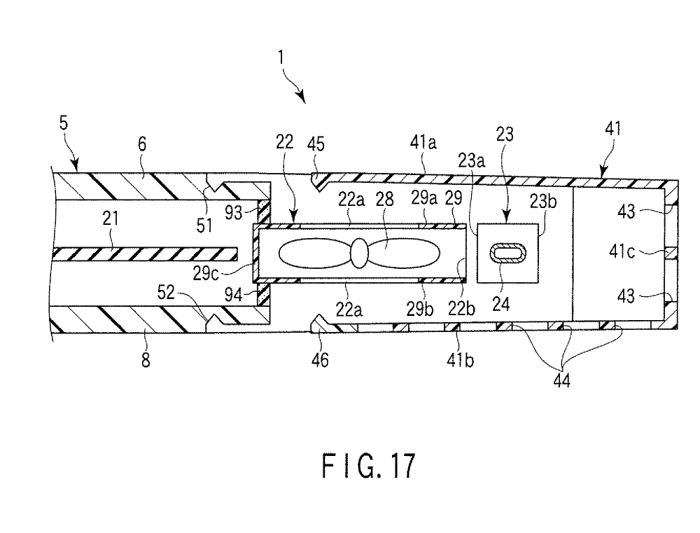

Referring to FIG. 17, one modification of the electronic apparatus 1 according to the seventh embodiment of the present invention will be described. As shown in FIG. 17, the electronic apparatus according to the present modification comprises, instead of the first and second ribs 91, 92, a first sponge member 93 interposed between the fan case 29 of the cooling fan 22 and the upper wall 6 and a second sponge member 94 interposed between the fan case 29 of the cooling fan 22 and the lower wall 8. The first and second sponge members 93, 94 are each located further inside the housing 5 than the inlet 22a of the cooling fan 22, and face the gap between the cooling fan 22 and the inner surface of the housing 5. The first and second sponge members 93, 94 are examples of a “raised part” of the present invention. This configuration can produce the same advantage as the seventh embodiment. The first and second sponge members 93, 94 may each be located between the inner surface of the housing 5 and circuit board 21.

The electronic apparatus 1 according to the first to seventh embodiments of the present invention have been described. However, the present invention is not limited to the above embodiments. The structural elements in the first to seventh embodiments may be used in combination as needed. Further, the present invention is not limited to the exact first to seventh embodiments, and may be embodied by modifying structural elements in the scope that does not go out of the subject at the stage of implementation.

In the first to seventh embodiments, the right wall 16 and rear wall 17 are described as examples of a “third wall” and a “fourth wall”, but the third wall and fourth wall are not limited to the right wall 16 and rear wall 17. Each of the third wall and fourth wall may be the front wall 14, left wall 15, right wall 16 and rear wall 17, or another wall. Further, a “first wall” and a “second wall” are not limited to the upper wall 6 and lower wall 8.

The open portion 31 is not limited to the one exposing the entire heat sink 23 in the first to seventh embodiments, and may be one exposing only a part of the heat sink 23. For example, in the fifth embodiment, the open portion 31 may expose the heat sink 23 and may not expose the heat sink 23. Each of the first and second portions 41a, 41b of the cover 41 may face only a part of the heat sink 23, and may not face the heat sink 23, for example, in the fifth embodiment.

The open portion 31 is not limited to the one exposing the entire cooling fan 22 in the first to seventh embodiments, and may be the one exposing only a part of the cooling fan 22. For example, in the fourth embodiment, the open portion 31 may expose the cooling fan 22 and may not expose the cooling fan 22. Each of the first and second portions 41a, 41b of the cover 41 may face only a part of the cooling fan 22, and may not face the cooling fan 22, for example, in the fourth embodiment. Instead of using the guides 81, 82, one of the guides 81, 82 may be used. Instead of using the ribs 91, 92, one of the ribs 91, 92 may be used. Instead of using the sponge members 93, 94, one of the sponge members 93, 94 may be used.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus, comprising
a heat sink;
a housing containing the heat sink, the housing comprising a first wall, a second wall located opposite to the first wall relative to the heat sink, a third wall extending between the first wall and second wall, and an open portion formed by continuously cutting out the first wall, second wall, and third wall and configured to expose at least a part of the heat sink to the outside; and
a cover detachably attached to the open portion, the cover comprising a first portion which joins with the first wall and faces at least a part of the heat sink, and a second portion which joins with the second wail and faces at least a part of the heat sink from a side opposite to the first portion, and a third portion which joins with the third wall.

2. The electronic apparatus of claim 1, further comprising:
a cooling fan in the housing, wherein
the open portion is configured to expose at least a part of the cooling fan to the outside, and
the first portion of the cover faces at least a part of the cooling fan, and the second portion faces at least a part of the cooling fan from a side opposite the first portion.

3. The electronic apparatus of claim 1, wherein
the cover comprises a first engaging member engaged with the first wall and a second engaging member engaged with the second wall, the cover being secured to the housing by an elastic force of the cover.

4. The electronic apparatus of claim 1, wherein
the cover comprises a vent and a dust filter attached to the vent.

5. The electronic apparatus of claim 1, further comprising a keyboard on the housing, wherein
the first portion of the cover is located below the keyboard and supports a part of the keyboard.

6. The electronic apparatus of claim 1, wherein
the housing comprises a fourth wall which is adjacent to the third wall, extends between the first wall and second wall, and forms a corner of the housing cooperatively with the third wall, the open portion being formed by cutting out the corner, and
the cover comprises a fourth portion which joins with the fourth wall and faces the heat sink from a direction different from the third wall, a first end portion of each of the first portion and second portion being supported by the third portion, and a second end portion of each of the first portion and second portion being supported by the fourth portion.

7. The electronic apparatus of claim 1, wherein
the housing comprises a guide configured to guide the cover, and
the cover is configured to be attached to and detached from the open portion by sliding along the guide.

8. The electronic apparatus of claim 2, further comprising a raised part facing a gap between an inner surface of the housing and cooling fan.

9. An electronic apparatus comprising:
a cooling fan;
a housing containing the cooling fan, the housing comprising a first wall, a second wall located opposite to the first wall relative to the cooling fan, a third wall extending between the first wall and second wall, and an open portion formed by continuously cutting out the first wall, second wall, and third wall and configured to expose at least a part of the cooling fan to the outside; and
a cover detachably attached to the open portion, the cover comprising a first portion which joins with the first wall and faces at least a part of the cooling fan, a second portion which joins with the second wall and faces at least a part of the cooling fan from a side opposite to the first portion, and a third portion which joins with the third wall.

10. The electronic apparatus of claim 9, wherein
the cover comprises a first lug engaged with the first wall and a second lug engaged with the second wall, the cover being secured to the housing by an elastic force of the cover.
